(19) United States
(12) Patent Application Publication
(10) Pub. No.: US 2025/0105499 A1
(43) Pub. Date: Mar. 27, 2025

(54) METHOD FOR MANUFACTURING WIRELESS COMMUNICATION DEVICE, WIRELESS COMMUNICATION DEVICE, AND ASSEMBLY OF WIRELESS COMMUNICATION DEVICES

(71) Applicant: Toray Industries, Inc, Tokyo (JP)

(72) Inventors: Ryuichi Tanaka, Otsu-shi (JP); Seiichiro Murase, Otsu-shi (JP); Junji Wakita, Otsu-shi (JP)

(73) Assignee: Toray Industries, Inc., Tokyo (JP)

(21) Appl. No.: 18/973,813

(22) Filed: Dec. 9, 2024

Related U.S. Application Data
(63) Continuation of application No. 17/298,783, filed on Jun. 1, 2021.

(30) Foreign Application Priority Data
Dec. 25, 2018 (JP) 2018-240796

(51) Int. Cl. H01Q 1/40; G06K 19/077; H01Q 9/42; H01Q 21/00; H10K 10/46; H10K 10/82; H10K 10/88

(52) U.S. Cl. CPC H01Q 1/40; G06K 19/077; H01Q 9/42; H01Q 21/0087; H10K 10/46; H10K 10/82; H10K 10/88

(57) ABSTRACT

A flexible wireless communication device with high position accuracy and low cost by a simple process is described, including a wireless communication device and a method for manufacturing a wireless communication device formed by bonding a first film substrate on which at least a circuit is formed and a second film substrate on which an antenna is formed, in which the circuit includes a transistor, and the transistor is formed by a step of forming a conductive pattern on the first film substrate, a step of forming an insulating layer on the film substrate on which the conductive pattern is formed, and a step of applying a solution including an organic semiconductor and/or a carbon material on the insulating layer and drying the solution to form a semiconductor layer.

### CROSS REFERENCE TO RELATED APPLICATIONS

This is a U.S. Continuation Application of U.S. application Ser. No. 17/298,783, filed on Jun. 1, 2021, which is the U.S. National Phase application of PCT/JP2019/048923, filed Dec. 13, 2019, which claims priority to Japanese Patent Application No. 2018-240796, filed Dec. 25, 2018, the disclosures of these applications being incorporated herein by reference in their entireties for all purposes.

### FIELD OF THE INVENTION

The present invention relates to a method for manufacturing the wireless communication device and the wireless communication device.

### BACKGROUND OF THE INVENTION

In recent years, development of the wireless communication device using radio frequency identification (RFID) technology as a non-contact type tag has been promoted. In an RFID system, wireless communication is performed between a wireless transmitter-receiver called a reader-writer and an RFID tag.

The RFID tag is made by embedding, processing, and tagging an RFID inlay, which includes a drive circuit constituted of a transistor, a capacitor, and the like, and an antenna for wireless communication with a reader-writer. The antenna installed in the tag receives a carrier wave transmitted from the reader-writer, and the drive circuit operates.

RFID tags have begun to be introduced in some IC cards such as transportation cards, product tags, and the like, and are expected to be used for various purposes such as logistics management, product management, and shoplifting prevention.

For that purpose, it is required that the RFID inlay is flexible and can be manufactured at low cost. One method of manufacturing the RFID inlay is to form an RFID drive circuit and an antenna on the same substrate. However, in this method, the size of the antenna is large and the RFID drive circuit must be formed in a portion where the antenna is not provided, and thus the RFID drive circuit cannot be formed at high density. Thus, the production efficiency becomes low, which causes an increase in cost.

Accordingly, a method is considered that, after forming RFID drive circuits and antennas at high density on separate substrates, the substrate on which the RFID drive circuits are formed is divided into a plurality of sections including one or more RFID chips, and then bonded to the antennas on the antenna substrate (see, for example, Patent Document 1).

### PATENT DOCUMENT

Patent Document 1: Japanese Patent Laid-open Publication No. 2005-520266

### SUMMARY OF THE INVENTION

However, in the method described in Patent Document 1, an RFID inlay of a method of mounting an IC chip is used. In this case, the wafer used for the IC chip is hard, and there is a problem that, when bending or pressure is applied, the base material such as a film or the IC chip is damaged, and the RFID tag malfunctions.

In view of the above problems, it is an object of the present invention to provide a method for manufacturing a wireless communication device which is resistant to bending, pressure, and friction and can accurately bond a connecting portion between an RFID circuit and an antenna.

The present invention has been made in view of the above problems and is a wireless communication device and a method for manufacturing a wireless communication device by bonding a first film substrate on which at least a circuit is formed and a second film substrate on which an antenna is formed, in which
the circuit includes a transistor, and
the transistor is formed by a step of forming a conductive pattern on the first film substrate,
a step of forming an insulating layer on the film substrate on which the conductive pattern is formed, and
a step of applying a solution including an organic semiconductor and/or a carbon material on the insulating layer and drying the solution to form a semiconductor layer.

According to the present invention, it is possible to obtain a flexible wireless communication device. Further, when a configuration is employed in which a circuit and a part of an antenna are overlapped, an area of an inlay can be reduced. Further, a manufacturing method of the present invention makes it possible to manufacture a wireless communication device with high position accuracy and low cost in a small number of steps.

### BRIEF DESCRIPTION OF THE DRAWINGS

FIG. 1A is a schematic view illustrating an example of a method for manufacturing a wireless communication device according to an embodiment of the present invention.

FIG. 1B is a schematic cross-sectional view of bonded portions of a first film substrate and a second film substrate.

FIG. 1C is a schematic view illustrating a positional displacement between an RFID circuit and an antenna.

FIG. 2 is a schematic plan view illustrating a first film substrate on which the RFID circuit is formed.

FIG. 3 is a schematic plan view illustrating a second film substrate on which an antenna circuit is formed.

FIG. 4A is a schematic plan view illustrating the wireless communication device according to the embodiment of the present invention.

FIG. 4B is a schematic cross-sectional view illustrating a connecting portion between the RFID circuit and the antenna.

FIG. 5 is a schematic cross-sectional view illustrating an example of a method for manufacturing the RFID circuit.

FIG. 6 is a schematic view illustrating an example of a method for manufacturing a wireless communication device according to an embodiment of the present invention.

FIG. 7 is a schematic view illustrating an example of a method for manufacturing a wireless communication device according to an embodiment of the present invention.

FIG. 8 is a schematic view illustrating an example of a method for manufacturing a wireless communication device according to an embodiment of the present invention.

FIG. 9 is a schematic view illustrating an example of a method for manufacturing a wireless communication device according to an embodiment of the present invention.

FIG. 10 is a schematic view illustrating an example of a method for manufacturing a wireless communication device according to an embodiment of the present invention.

FIG. 11 is a schematic plan view illustrating an example of a wireless communication device according to an embodiment of the present invention.

FIG. 12A is a schematic plan view illustrating an example of an overlapping portion between a circuit and an antenna.

FIG. 12B is a schematic cross-sectional view illustrating an example of an overlapping portion between a circuit and an antenna.

FIG. 12C is a schematic cross-sectional view illustrating an example of an overlapping portion between a circuit and an antenna.

FIG. 12D is a schematic cross-sectional view illustrating an example of an overlapping portion between a circuit and an antenna.

### DETAILED DESCRIPTION OF EMBODIMENTS OF THE INVENTION

Hereinafter, embodiments for carrying out the present invention will be described in detail. Note that the present invention is not limited to the following embodiments.

In the present invention, a circuit means a circuit constituted of an electronic circuit including transistors, capacitors, electrode wiring, and so on, and a connecting portion for electrically connecting the electronic circuit and an antenna using a connection pad or an antenna coil. Specifically, the circuit refers to a circuit that includes at least one or more of rectifier circuit, demodulation circuit, logic circuit, modulation circuit, and storage circuit used in RFID, transceivers, wireless microphones, sensor modules for IoT, RF remote controllers, lighting control systems, keyless entry, or the like. Further, the antenna is a device for receiving radio waves from a reader-writer and driving a circuit to transmit information to the reader-writer. While there is an RFID circuit as a circuit constituted of an electronic circuit including transistors, capacitors, electrode wiring, and so on, and a connecting portion for electrically connecting the electronic circuit and an antenna using a connection pad or an antenna coil, embodiments for carrying out the present invention will be described by taking an RFID circuit as an example.

### Embodiment 1

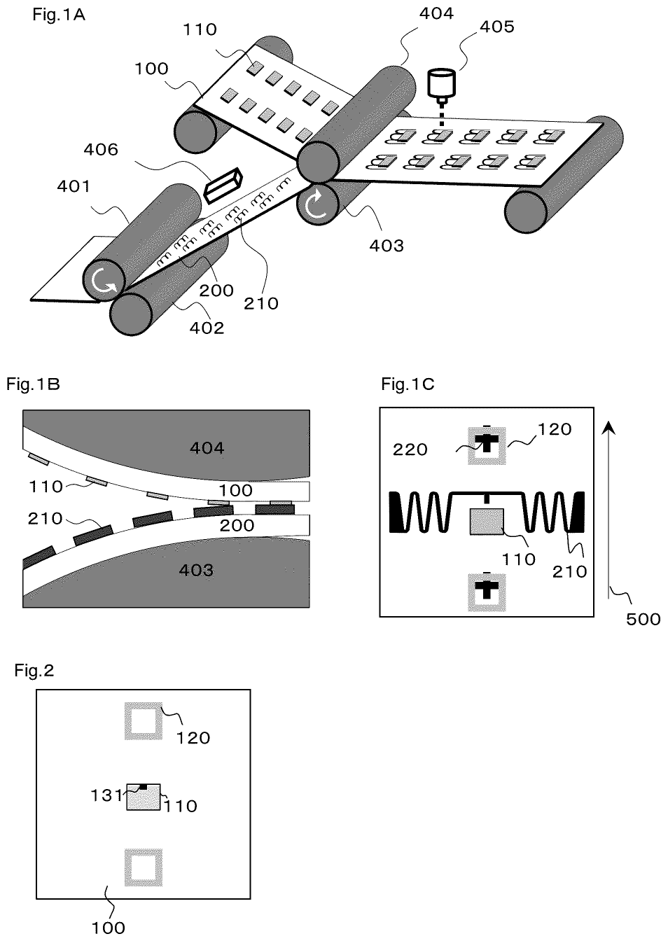

FIG. 1A is a schematic view illustrating an outline of a method for manufacturing a wireless communication device according to Embodiment 1 of the present invention. In this Embodiment 1, a step of bonding a first film substrate 100 on which an RFID circuit 110 is formed and a second film substrate 200 on which an antenna 210 is formed is schematically illustrated. FIG. 1B is a schematic view of bonded portions as viewed from a side.

A material used for the first film substrate may be any material as long as at least a surface on which an electrode system is arranged is an insulating film. Organic materials such as polyimide, polyvinyl alcohol, polyvinyl chloride, polyethylene terephthalate, polyvinylidene fluoride, polysiloxane, polyvinylphenol (PVP), polyester, polycarbonate, polysulfone, polyethersulfone, polyethylene, polypropylene, polyphenylene sulfide, polyparaxylene, cellulose, or the like are preferably used, but the material is not limited thereto.

A material used for the second film substrate may be any material as long as a surface on which the antenna is arranged is an insulating film, and a similar material to that of the first film substrate, paper, or the like can be used.

The RFID circuit 110 is formed in an array of two rows in a long side direction of the first film substrate 100. The RFID circuit 110 includes a transistor. As the transistor, an organic field effect transistor is preferable.

The antenna 210 is formed in an array of two rows in a long side direction of the second film substrate 200. The number of columns in these arrays is not particularly limited, and one or more columns are preferable.

A bonding nip roll 404 is a roll for applying pressure to the first film substrate 100 and the second film substrate 200 for bonding. A bonding feed roll 403 is a roll for conveying both substrates at a predetermined speed after bonding them. Thus, bonding and conveying are performed.

FIG. 2 is a schematic plan view illustrating the first film substrate on which the RFID circuit is formed. The RFID circuit 110, an alignment mark 120, and an upper electrode wiring 131 are formed on the first film substrate 100. The upper electrode wiring 131 is included in the RFID circuit 110 and is a connection wiring with the antenna. FIG. 2 illustrates a state in which only one RFID circuit 110 is formed for ease of understanding, but of course there is no limit to the number thereof. The same applies to the alignment mark 120 and the upper electrode wiring 131. A method of forming the RFID circuit will be described later.

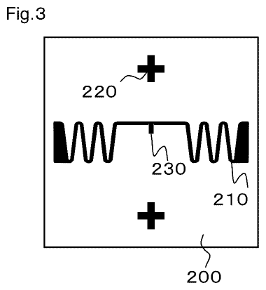

FIG. 3 is a schematic plan view illustrating the second film substrate on which the antenna is formed. An antenna 210, an alignment mark 220, and an antenna wiring 230 are formed on the second film substrate 200. The antenna wiring 230 is a part of the antenna 210 and is a connection wiring with the RFID circuit 110. FIG. 3 illustrates a state in which only one antenna 210 is formed for ease of understanding, but of course the number is not limited. The same applies to the alignment mark 220 and the antenna wiring 230.

As a method for forming the antenna 210, there are publicly known methods such as a method of processing a metal foil such as copper foil or aluminum foil into an antenna using a punching blade and transferring it to a base material (hereinafter referred to as a punching blade method), a method of etching a metal foil attached to a base material such as a plastic film using a resist layer formed on the metal foil as a mask, a method of printing a conductive paste on a base material such as a plastic film in a pattern corresponding to an antenna and curing it by heat or light (hereinafter referred to as a printing method), and a method of etching a metal film formed by vapor deposition using a resist layer formed on the metal film as a mask.

The material used for the antenna is not particularly limited, and Ag, Au, Cu, Pt, Pb, Sn, Ni, Al, W, Mo, Cr, Ti, carbon, indium and the like can be used. As the metal foil material used in the punching blade method, Cu and Al are preferable from the viewpoint of cost and antenna performance, and as a metal material included in a conductive paste used in the printing method, Ag is preferable from the viewpoint of cost and antenna performance.

A coating film is formed on the second film substrate 200 using a photosensitive paste, and thereafter a pattern corresponding to electrodes and wirings is formed using photolithography. Thus, an antenna substrate with wirings and electrodes can be formed.

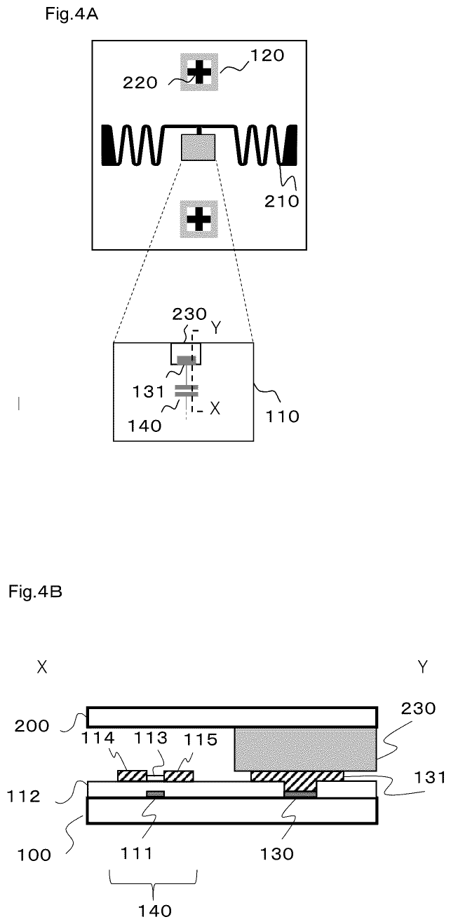

FIG. 4A is a schematic plan view illustrating a wireless communication device manufactured by bonding the first film substrate illustrated in FIG. 2 and the second film substrate illustrated in FIG. 3. A surface of the RFID circuit 110 side formed on the first film substrate 100 and a surface of the antenna 210 side formed on the second film substrate 200 are bonded to each other. The bonding is performed by aligning the alignment marks 120 and 220. Further, as illustrated in a partially enlarged view of an inside of the RFID circuit 110 illustrated in FIG. 4A, the antenna wiring 230 on the second film substrate and the upper electrode wiring 131 on the first film substrate are connected.

FIG. 4B is a schematic cross-sectional view taken along a dashed line X-Y of FIG. 4A. In FIG. 4B, a TFT unit 140, which is one of operating parts of the circuit, and an electrode portion, which is a connecting portion with the antenna, are formed on the first film substrate. In the electrode portion, a pattern (contact hole) to be an opening is formed in an insulating layer 112 in order to obtain conduction from a lower electrode wiring 130. Then, the upper electrode wiring 131 and the antenna wiring 230 are connected. The upper electrode wiring 131 and the antenna wiring 230 may be directly connected, or may be connected after applying a conductive paste to the connecting portion, or may be connected after applying the non-conductive paste to at least a portion between the upper electrode wiring 131 and the antenna wiring 230. By directly bonding the RFID circuit 110 on the first film substrate 100 and the antenna 210 on the second film substrate 200 to face each other in this manner, it is not necessary to use wires, conductive tapes, or the like, and thus bonding with less unevenness is possible.

This will be described by returning to FIG. 1A. Note that the circuit 110 formed on a lower side of the first film substrate 100 is originally drawn with a broken line, but is illustrated with a solid line for ease of understanding. Similarly, the wireless communication device manufactured by laminating the first film substrate 100 and the second film substrate 200 is also illustrated by a solid line. A plurality of wireless communication devices (assembly of wireless communication devices) is manufactured on the two film substrates bonded in this manner.

An alignment camera 405 provided in the process of bonding the first film substrate and the second film substrate measures and detects the amount of displacement between the first film substrate 100 and the second film substrate 200 in a conveyance direction. Alignment marks (not illustrated in FIG. 1A) are formed on the first film substrate 100 and the second film substrate 200, respectively, and the amount of displacement is detected from their relative displacements.

Regarding the alignment marks, there is no regulation on the size and shape as long as it can be detected within the field of view of the camera. Further, if the amount of displacement can be detected from a manner that the RFID circuit 110 and the antenna 210 overlap, the alignment marks do not need to be provided.

The alignment camera may be of any type or method as long as the alignment marks can be detected, and examples thereof include an area camera, a line scan camera, and the like. Alternatively, a strobe may be used for periodic imaging.

In FIG. 1A, the displacement between the first film substrate 100 and the second film substrate 200 is detected after the bonding, but it may be detected before the bonding. For example, two alignment cameras are provided on an upstream side of the bonding portion so that the alignment marks of each substrate is detected before the first film substrate 100 and the second film substrate 200 pass through the bonding portion. Then, the amount of displacement may be calculated by detecting the position of each substrate before bonding by each camera and calculating the distance from each detection position to the bonding position.

Correction of the displacement may be performed on-time, but it is usual to set an allowable range of the amount of displacement and perform it when the allowable range is exceeded. The allowable range of displacement is set according to the size of the connecting portion of the RFID circuit and the connecting portion of the antenna.

The correction of the displacement is preferably performed by changing conveyance tension of the first film substrate or the second film substrate according to the amount of displacement. The change in the conveyance tension can be made by using, for example, a tension adjusting nip roll 402 and a tension adjusting feed roll 401 illustrated in FIG. 1A, but is not limited to this as long as it is a mechanism that can change the tension.

In the configuration of FIG. 1A, as illustrated in FIG. 1C, when the alignment mark 220 of the second film substrate is bonded with a displacement from the alignment mark 120 of the first film substrate in a conveyance direction 500, only the second film substrate 200 is stretched so as to generate tension that cannot be restored even after stretching by reducing the rotation speed of the tension adjusting feed roll 401 with respect to the rotation speed of the bonding feed roll 403. In this manner, the second film substrate 200 can be plastically deformed and the displacement can be adjusted.

To what degree the rotation speed of the tension adjusting feed roll 401 is slowed down according to the amount of displacement is determined by physical properties such as a glass transition temperature and a thickness of the second film substrate and how much plastic deformation is caused by the temperature.

In a case of a film that is difficult to stretch, the film substrate may be heated by a heater 406 as illustrated in FIG. 1A in order to facilitate stretching. In particular, the stretching effect can be remarkably obtained by setting the temperature above the softening point of the second film substrate. However, if the temperature variation is large, it may be locally stretched or wrinkled, and thus the placement may be performed after checking a temperature distribution and temperature accuracy. Examples of the heating method include publicly known methods such as hot air, infrared rays, and heat rolls.

As a control method for correcting the amount of displacement, for example, control is performed to convey with tension further increased by 10 N from the set tension when a displacement of 100 μm or more is detected, and return the tension to the set tension when the displacement returns to 100 μm or less. It is a control to increase the tension when the amount of displacement exceeds a certain threshold, and a threshold for the amount of displacement for changing the tension may be set in several steps. As the amount of displacement used for control, it is preferable to use an average value of several detections in consideration of the fact that the detection of the amount of displacement includes a measurement error. Further, regarding the change of tension, the tension may be changed little by little according to the amount of displacement without setting a threshold for the amount of displacement as described above.

Further, since the conveyance speeds of the first film substrate 100 and the second film substrate 200 after passing through the bonding feed roll 403 are the same, it is possible to eliminate concerns for displacements or peel off due to shearing after bonding, and the like.

In the example of FIG. 1A, tension of the second film substrate 200 is adjusted, but tension of the first film substrate 100 may be adjusted.

In the examples of FIGS. 1A and 1B, a surface of the RFID circuit side of the first film substrate and a surface of the antenna side of the second film substrate are bonded together. That is, the surfaces of both the substrates are bonded to each other. In this manner, the RFID circuit and the antenna can be directly connected and power can be supplied. Further, even if the first film substrate 100 or the second film substrate 200 is damaged by friction during processing, wireless communication is possible as long as the damage does not reach an inner surface.

Note that the method of bonding the first film substrate and the second film substrate is not limited to the above mode. Specifically, a back surface side of one of the substrates and a front surface of the other substrate may be bonded together, or back surfaces of both the substrates may be bonded to each other. In cases of these embodiments, wireless communication is possible by supplying power by a publicly known non-contact coupling method such as a coupling method using capacitance or a coupling method using electromagnetic induction.

However, from the viewpoint of stability of wireless communication, abrasion resistance in the manufacturing process, or the like, it is more preferable to bond the surface of the RFID circuit side of the first film substrate and the surface of the antenna side of the second film substrate.

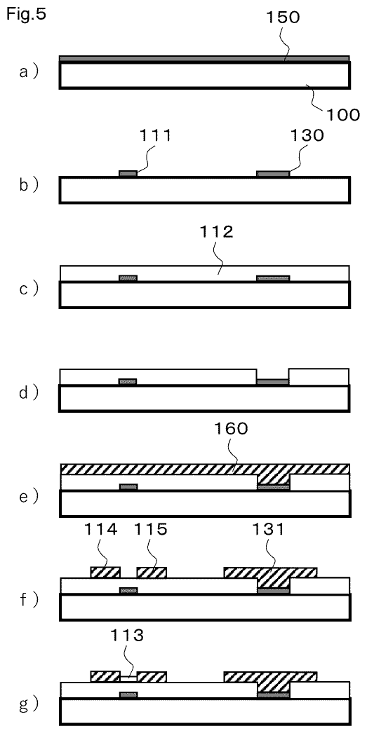

FIG. 5 is a schematic cross-sectional view illustrating an example of a method for manufacturing a transistor, which is one of the elements constituting the RFID circuit 110.

First, in FIG. 5(a), a lower conductive film 150 is formed on the first film substrate 100. Examples of a method for forming the lower conductive film 150 include a resistance heating vapor deposition method, an electron beam method, a sputtering method, a plating method, a CVD method, and the like. Further, a method can be mentioned in which a paste including an electric conductor and a photosensitive organic component is applied onto a substrate by a publicly known coating method such as an inkjet method, a printing method, an ion plating method, a blade coating method, a slit die coating method, a screen printing method, a bar coater method, a molding method, a printing transfer method, and a dipping pulling method, and then the coated film is dried to eliminate the solvent.

As a material of the lower conductive film 150, silver, copper, and gold are preferable from the viewpoint of conductivity, and silver is more preferable from the viewpoint of cost and stability.

Next, in FIG. 5(b), the lower conductive film 150 is patterned to form a gate electrode 111 and the lower electrode wiring 130 including the connecting portion with the antenna. Pattern processing by publicly known photolithography is preferable. When the lower conductive film 150 is not photosensitive, publicly known pattern processing using a photoresist can be used. When a paste including a conductor and a photosensitive organic component is applied onto a substrate to form the lower conductive film 150, the photosensitive conductive film can be photolithographically processed. In this manner, the gate electrode 111 and the lower electrode wiring 130, which are conductive patterns, are formed on the first film substrate 100.

Next, in FIG. 5(c), the gate insulating layer 112 is formed on the gate electrode 111 and the lower electrode wiring 130 including the connecting portion with the antenna. The material used for the gate insulating layer is not particularly limited, but can include an inorganic material such as silicon oxide and alumina; an organic material such as polyimide, polyvinyl alcohol, polyvinyl chloride, polyethylene terephthalate, polyvinylidene fluoride, polysiloxane, and polyvinylphenol (PVP); or a mixture of inorganic material powder and organic material.

The method for producing the gate insulating layer is not particularly limited, and examples thereof include a method in which a coating film, which is obtained by applying a raw material composition onto a substrate on which a gate electrode is formed and performing drying, is heat-treated as necessary. Examples of the coating method include publicly known coating methods such as a blade coating method, a slit die coating method, a screen printing method, a bar coater method, a molding method, a printing transfer method, a dipping pulling method, and an inkjet method.

Next, in FIG. 5(d), the gate insulating layer 112 on the lower electrode wiring 130 is removed to form a contact hole. This is performed for a portion connecting the lower electrode wiring and the upper electrode wiring. When the gate insulating layer 112 is obtained by using a paste having a photosensitive organic component in the step of FIG. 5(c), contact holes can be formed by patterning by photolithography.

Next, in FIG. 5 (e), an upper conductive film 160 including the conductor and the photosensitive organic component is formed on the gate insulating layer 112. Since the organic binder includes a photosensitive organic component, the electrode pattern can be processed by photolithography without using a resist, and the productivity can be further improved. As a method for forming the upper conductive film 160, coating is performed by a publicly known coating method such as a blade coating method, a slit die coating method, a screen printing method, a bar coater method, a molding method, a printing transfer method, a dipping pulling method, and an inkjet method, and thereafter a method of drying the coating film to eliminate the solvent can be mentioned.

Next, in FIG. 5(f), the upper conductive film 160 is patterned to form a source electrode 114, a drain electrode 115, and the upper electrode wiring 131 including the connecting portion with the antenna. By exposing these from the back surface through the first film substrate 100 using the gate electrode 111 as a mask, the source electrode 114 and the drain electrode 115 can be aligned with high accuracy without alignment. However, they may be formed similarly as in the case of the gate electrode 111 and the lower electrode wiring 130 in FIG. 5(b).

Finally, in FIG. 5(g), an organic semiconductor layer 113 is formed between the source electrode 114 and the drain electrode 115. The material used for the organic semiconductor layer is an organic semiconductor and/or a carbon material. Examples of the carbon material include carbon nanotubes (CNT), graphene, fullerenes, and the like, but CNT is preferable in terms of suitability for the coating process and high mobility. Furthermore, CNTs having a conjugated polymer attached to at least a part of the surface (hereinafter referred to as CNT composite) are particularly preferable because they have excellent dispersion stability in a solution and high mobility can be obtained.

As a method for forming the organic semiconductor layer 113, a dry method such as resistance heating vapor deposition, electron beam, sputtering, or CVD can be used, but it is preferable to use the coating method from the viewpoint of manufacturing cost and compatibility with a large area. Examples of the coating method include publicly known coating methods such as a blade coating method, a slit die coating method, a screen printing method, a bar coating method, a mold method, a printing transfer method, a dipping pulling method, and an inkjet method. Note that step (g) may be performed before steps (e) and (f). In this manner, the organic semiconductor layer 113 is formed on the gate insulating layer 112.

### Embodiment 2

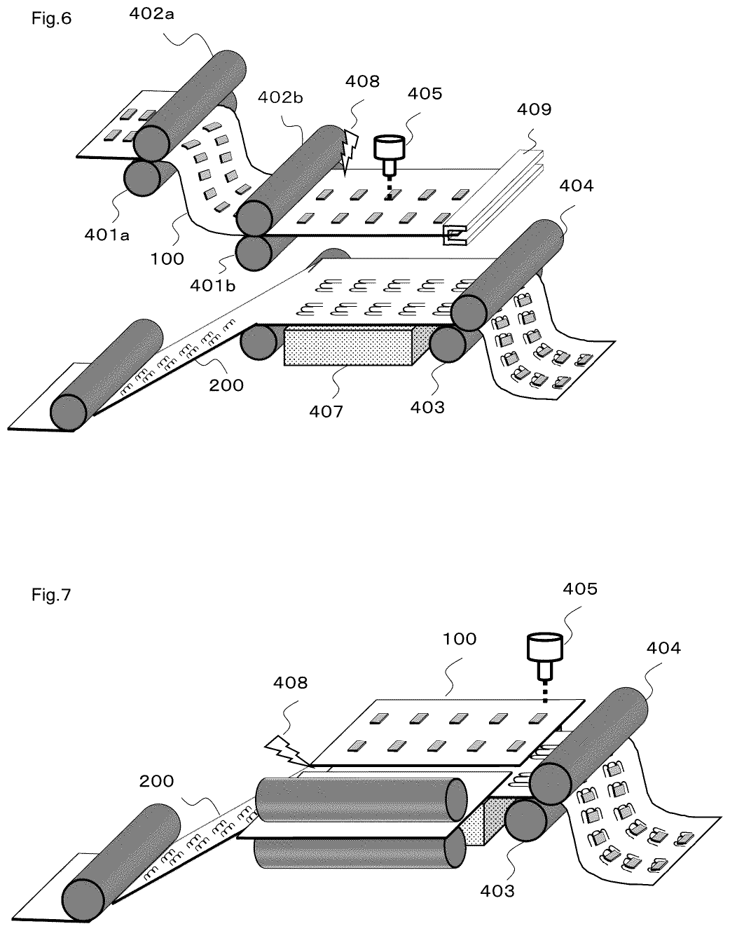

FIG. 6 is a schematic view illustrating an outline of a method for manufacturing a wireless communication device according to Embodiment 2 of the present invention. In Embodiment 2, conveyance directions of the first film substrate 100 and the second film substrate 200 are the same direction, and are intermittently conveyed in the long side direction so as to face each other. That is, once the both are conveyed by a certain amount, they are temporarily stopped. When stopped, the first film substrate 100 is fixed by a film conveyance grip 409. A tension adjusting feed roll 401a and a tension adjusting nip roll 402a cut the conveyance tension, and with the first film substrate 100 loosened, a tension adjusting feed roll 401b, a tension adjusting nip roll 402b, and a conveyance grip are lowered.

After they are lowered, the alignment camera 405 detects a displacement between the first film substrate 100 and the second film substrate 200 in a state of being close to each other. The displacement is checked at least at two or more points of respective alignment marks of the first film substrate 100 and the second film substrate 200, and the positions are aligned in the long side direction and the short side direction. The alignment is performed, for example, by moving a stage 407 with the second film substrate 200 sucked on the stage 407.

The first film substrate 100 is further lowered, the first film substrate 100 is placed on the second film substrate 200, and then only the first film substrate 100 is (half) cut using a film cutting blade 408. Thus, the first film substrate 100 is divided into sheets including a plurality of RFID circuits. Thereafter, grip of the film conveyance grip 409 is released, and the tension adjusting feed roll 401b, the tension adjusting nip roll 402b, and the conveyance grip 409 are raised. By conveying the second film substrate 200 and passing it through the bonding feed roll 403 and the bonding nip roll 404, the first film substrate 100 and the second film substrate 200 are nipped and bonded.

The configuration of FIG. 6 is an example, and other configurations may be used as long as they includes a step of cutting one of the film substrates when the conveyance is stopped, a step of detecting displacement of the first film substrate and the second film substrate, an alignment step, and a bonding step.

### Embodiment 3

FIG. 7 is a schematic view illustrating an outline of a method for manufacturing a wireless communication device according to Embodiment 3 of the present invention. In Embodiment 3, the first film substrate 100 and the second film substrate 200 are manufactured through similar steps to those in Embodiment 2 except that they are arranged so as to be orthogonal to each other.

Due to the influence of vertical and horizontal stretching during the film manufacturing process, for example, heat shrinkage in the long side direction of a PET film is often larger than that in the short side direction. Therefore, by making the first film substrate and the second film substrate orthogonal to each other, their respective long side direction and short side direction are bonded to each other, and thus the amount of displacement is smaller than that when the long side directions are bonded to each other.

### Embodiment 4

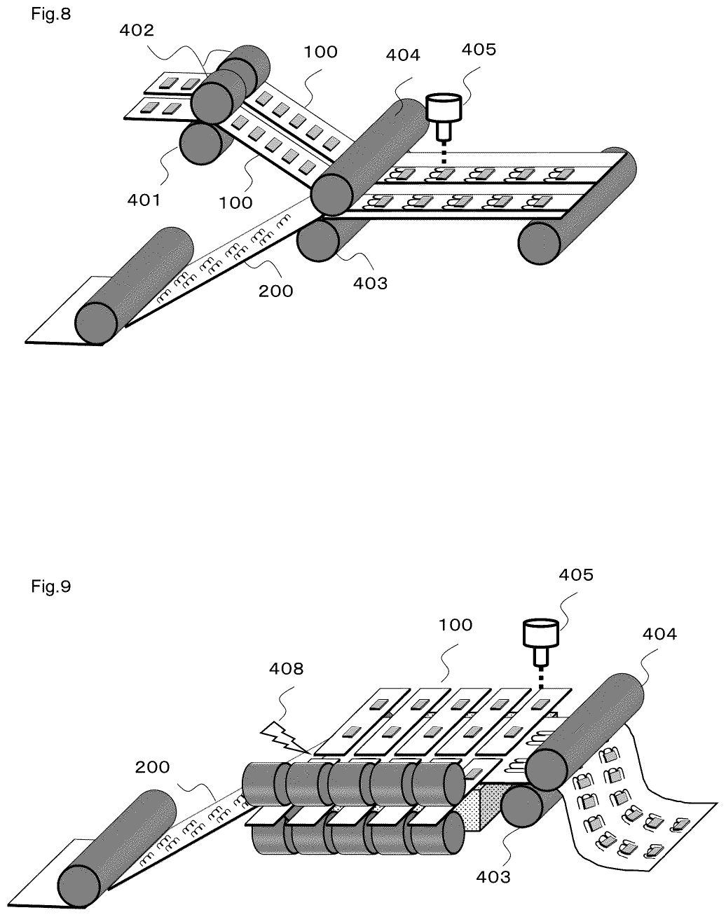

FIG. 8 is a schematic view illustrating an outline of a method for manufacturing a wireless communication device according to Embodiment 4 of the present invention. In Embodiment 4, a step of dividing the first film substrate 100 into two or more, and a step of adjusting a distance between the divided first film substrates in a direction perpendicular to the conveyance to a distance between antenna rows in a substrate width direction of the second film substrate are added to Embodiment 1, and a tension adjusting feed roll 401 and a tension adjusting nip roll 402 corresponding to each of the divided first film substrates 100 are provided.

By controlling the position of the divided first film substrate in the short side direction with, for example, “EPC” (registered trademark, Edge Position Control) or the like, alignment in the short side direction is possible in addition to displacement in the long side direction.

By the above manufacturing method, it becomes possible that the circuit 110 formed in an array on the first film substrate and the antenna 210 formed in an array on the second film substrate are aligned even if their respective array pitches in the film width direction are different.

### Embodiment 5

FIG. 9 is a schematic view illustrating an outline of a method for manufacturing a wireless communication device according to Embodiment 5 of the present invention. In Embodiment 5, it is manufactured through similar steps to those in Embodiment 4 except that the first film substrate 100 and the second film substrate 200 are arranged so as to be orthogonal to each other.

### Embodiment 6

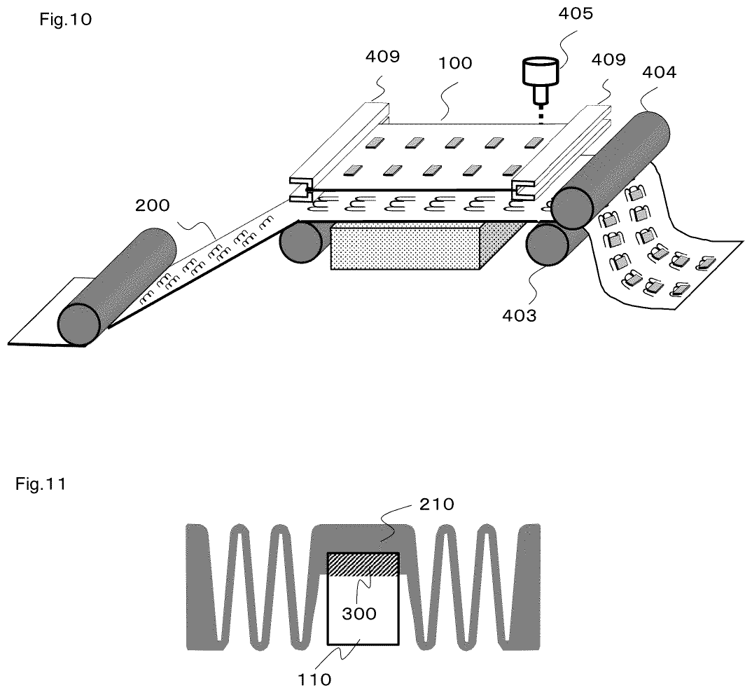

FIG. 10 is a schematic view illustrating an outline of a method for manufacturing a wireless communication device according to Embodiment 6 of the present invention. In Embodiment 6, the second film substrate 200 has a similar shape to that of Embodiment 2, except that the first film substrate 100 has a sheet form. The RFID circuit is formed in an array of one or more rows in the long side direction of the first film substrate in a sheet form.

The second film substrate 200 is intermittently conveyed in the long side direction. When stopped, the first film substrate 100 is conveyed onto the second film substrate and fixed by the film conveyance grip 409. Any other configuration may be used as long as it is a mechanism that can stop the first film substrate 100 after being conveyed onto the second film substrate. For example, a mechanism capable of sucking a part or the entire surface of the first film substrate may be provided, and the first film may be picked up and then conveyed onto the second substrate.

After the first film substrate and the second film substrate are stopped, the alignment camera 405 detects the displacement between the first film substrate 100 and the second film substrate 200 in a state of being close to each other. The displacement is checked at least at two or more points of respective alignment marks of the first film substrate 100 and the second film substrate 200, and the positions are aligned in the long side direction and the short side direction. Alignment is performed by moving the film conveyance grip 409.

Further, the first film substrate 100 is lowered, and the first film substrate 100 is placed on the second film substrate 200. Thereafter, the grip of the film conveyance grip 409 is released, and the film conveyance grip 409 is raised. By conveying the second film substrate 200 and passing it through the bonding feed roll 403 and the bonding nip roll 404, the first film substrate 100 and the second film substrate 200 are nipped and bonded.

Further, in all the embodiments, a step of applying a conductive paste to the connecting portion between the RFID circuit 110 formed on the first film substrate 100 and the antenna 210 formed on the second film substrate 200 before bonding may be provided. Further, a step of applying the non-conductive paste on at least a part between the first film substrate 100 and the second film substrate 200 may be provided.

As the conductive paste, silver paste, carbon paste, indium paste, and the like can be used, and as the non-conductive paste, a publicly known paste including a urethane resin, an epoxy resin, and an acrylic resin can be used.

Examples of the method for applying the conductive paste and the non-conductive paste include publicly known methods such as a screen printing method, a bar coating method, a printing transfer method, an inkjet method, and a dispenser method.

### Embodiment 7

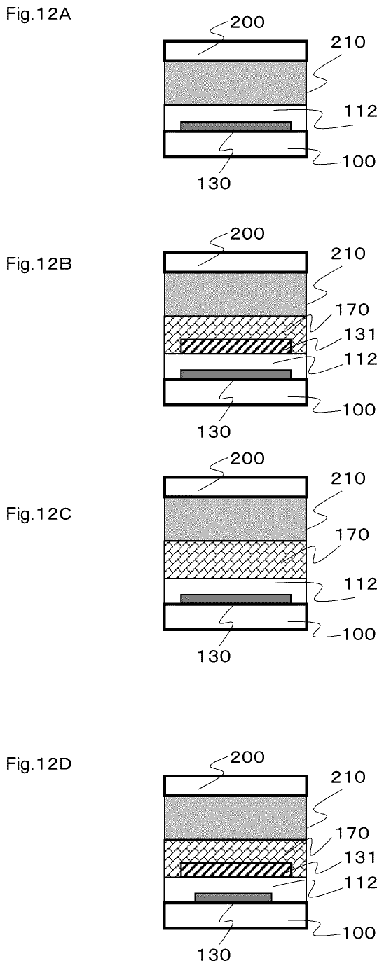

FIG. 11 is a schematic plan view illustrating an outline of a wireless communication device according to Embodiment 7 of the present invention. Embodiment 7 is characterized in that the circuit 110 and a part of the antenna 210 are designed to be intentionally overlapped with each other. FIG. 12A is a schematic cross-sectional view of an overlapping portion 300 of the circuit and the antenna illustrated in FIG. 11. As illustrated in FIG. 12A, the area of the overlapped portion can be reduced by arranging the lower electrode wiring 130, which is a part of the circuit, so as to overlap the antenna 210. Further, the overlapping portion may be used as a wiring for connecting the circuit and the antenna, but it can also be used as a parallel plate capacitor. In this case, the lower electrode wiring 130, the insulating layer 112, and the antenna 210 can be used to form a parallel plate capacitor. The capacitance is determined by the area of overlap of the lower electrode wiring 130 and the antenna 210 and the dielectric constant of the insulating layer. The shape in which the lower electrode wiring 130 and the antenna 210 overlap is described as a rectangle as an example, but any shape may be used. Further, the material and forming method of each layer are as illustrated in Embodiment 1.

It is important that the present invention includes a step of forming a circuit including an organic semiconductor layer using an organic semiconductor and/or a carbon material on a film substrate. With the inorganic semiconductor, since a circuit is formed on a wafer and thereafter it is made into a chip of several mm square to be mounted, it is difficult to obtain the effects of the present invention in terms of configuration and size.

### Embodiment 8

FIGS. 12B, 12C, and 12D are schematic cross-sectional views illustrating an outline of a wireless communication device according to Embodiment 8 of the present invention. In Embodiment 8, an insulating adhesive layer 170 is formed as an adhesive so as to be in contact with the antenna 210. Therefore, it is possible to form a parallel plate capacitor using any one of the lower electrode wiring 130, the insulating layer 112, the upper electrode wiring 131, the adhesive layer 170, and the antenna 210, and to connect wirings. Although the adhesive layer 170 is described as a single layer, similar effects can be obtained by using a plurality of adhesive layers 170 having different dielectric constants. FIG. 12B can be regarded as a parallel plate capacitor in which an adhesive layer 170 is formed between the antenna 210 and the upper electrode wiring 131, and a parallel plate capacitor in which an insulating layer 112 is formed between the upper electrode wiring 131 and the lower electrode wiring 130. Further, as illustrated in FIG. 12C, it can be made as a parallel plate capacitor in which an insulating layer 112 and an adhesive layer 170 are formed between the antenna 210 and the lower electrode wiring 130. As illustrated in FIG. 12D, it may be made as a parallel plate capacitor having the same configuration as that of FIG. 12B but having a smaller shape of the lower electrode wiring 130 and a different area of the parallel plate.

Further, by forming a part or the entire surface of the adhesive layer 170 on either the first film substrate 100 or the second film substrate 200 and bonding them by the manufacturing method of any one of Embodiments 1 to 6, a substrate that is flexible and has less unevenness can be obtained, and thereby a wireless communication circuit resistant to bending and pressure can be obtained. Furthermore, since the displacement is detected and bonding is performed with high accuracy, variations in capacitance of the parallel plate capacitor formed in the overlapping portion 300 of the circuit and the antenna can also be reduced.

The adhesive layer is formed of a publicly known resin such as a urethane resin, an epoxy resin, or an acrylic resin, and may include a publicly known insulating material such as silica, titanium oxide, or granular glass.

Further, in Embodiments 7 and 8, although the parallel plate capacitor has been described as an example, from the viewpoint of reducing the area of the inlay, it is sufficient if a part of the circuit overlaps with the antenna, and a member other than the antenna may be used with respect to the capacitance and resistance of the circuit.

Further, as a modification example, it is also possible to form a release layer between a second film substrate and an antenna in advance and, after bonding by the method of any one of Embodiments 1 to 6, peel off the second film substrate to transfer the antenna to the circuit side.

The method for manufacturing an RFID wireless communication device according to the present invention can be used for manufacturing an RFID tag as an inlay. The form of the RFID tag is not particularly limited, and examples thereof include a seal tag, a price tag, packaging with an RFID tag, and the like.

Examples of the method for manufacturing the seal tag include a method including at least the following two steps.
(1) Step in which a PET film (first film substrate) on which an RFID circuit is formed and an antenna film (second film substrate) formed using the PET film are bonded together by the method described in the present invention, thereby producing an RFID inlay.
(2) Step in which, out of both, front and back surfaces of the RFID inlay, an adhesive is applied to a side surface (that is, a back surface) where a first film substrate is not bonded, a release paper is laminated on this back surface, and a surface sheet on which printing such as printing letters is possible is laminated with an adhesive on a surface (that is, a front surface) on the side where the first film substrate is formed, and then scraping is performed.

Examples of the method for manufacturing the price tag include a method including at least the following two steps.
(1) Step in which a PET film (first film substrate) on which an RFID circuit is formed and an antenna film (second film substrate) formed using paper are bonded together by the method described in the present invention, thereby producing an RFID inlay.
(2) Step in which a surface paper on which a price, a product name, and the like are printed is laminated with an adhesive on a surface (that is, a front surface) on the side where the first film substrate is formed.

Examples of the method for manufacturing an RFID-tagged package include a method including at least the following two steps.
(1) Step in which a package film (first film substrate) on which an RFID circuit is formed and an antenna film (second film substrate) formed using the PET film are bonded together by the method described in the present invention, thereby producing an RFID inlay. Note that examples of a package film include a PET bottle label film, on which a product name, a product image, and the like are printed. In this case, the antenna pattern can be formed by a printing method using a conductive paste when printing the product name and the product image.
(2) Step in which a surface paper on which a price, a product name, and the like are printed is laminated with an adhesive on a surface (that is, a front surface) on the side where the first film substrate is formed.

### Description of Reference Signs

100: First film substrate
110: RFID circuit
111: Gate electrode
112: Insulating layer
113: Organic semiconductor layer
114: Source electrode
115: Drain electrode
120: Alignment mark
130: Lower electrode wiring
131: Upper electrode wiring (connecting portion)
140: TFT unit
150: Lower conductive film
160: Upper conductive film
170: Adhesive layer
200: Second film substrate
210: Antenna
220: Alignment mark
230: Antenna wiring (connecting portion)
300: Overlapping portion of circuit and antenna
401,401a,401b: Tension adjusting feed roll
402,402a,402b: Tension adjusting nip roll
403: Bonding feed roll
404: Bonding nip roll
405: Alignment camera
406: Heater
407: Stage
408: Film cutting blade
409: Film conveyance grip
500: Arrow indicating conveyance direction of first film substrate and second film substrate

1. A method for manufacturing a wireless communication device by bonding a first film substrate on which at least a circuit is formed and a second film substrate on which at least an antenna is formed, wherein:
the circuit includes a transistor, and
the transistor is formed by:
a step of forming a conductive pattern on the first film substrate,
a step of forming an insulating layer on the film substrate on which the conductive pattern is formed, and
a step of applying a solution including an organic semiconductor and/or a carbon material on the insulating layer and drying the solution to form a semiconductor layer; wherein:
the circuit is formed in an array of one or more rows in a long side direction of the first film substrate,
the antenna is formed in an array of one or more rows in a long side direction of the second film substrate,
the first film substrate and the second film substrate are conveyed in the long side direction, and the bonding is continuously performed,
the bonding includes:
a step of correcting the amount of displacement between the first film substrate and the second film substrate in a conveyance direction; and
a step of correcting a position of the first film substrate or the second film substrate according to the amount of displacement.
wherein the method includes a step of measuring an amount of displacement between the first film substrate and the second film substrate in a conveyance direction by changing a conveyance tension of the first film substrate or the second film substrate.

2. The method for manufacturing the wireless communication device according to claim 1, wherein a surface of a circuit side of the first film substrate and a surface of an antenna side of the second film substrate are bonded together.

3. The method for manufacturing the wireless communication device according to claim 1, wherein:
measuring the amount of displacement between the first film substrate and the second film substrate in the conveyance direction involves changing the conveyance tension of the first film substrate and the second film substrate.

4. The method for manufacturing the wireless communication device according to claim 1, further comprising:
a step of measuring the amount of displacement in the conveyance direction with an alignment camera.

5. The method for manufacturing the wireless communication device according to claim 1, further comprising:
a step of measuring the amount of displacement in the conveyance direction with an alignment camera; and
a step of correcting the amount of displacement by changing a conveyance tension of the first film substrate or the second film substrate.

6. The method for manufacturing the wireless communication device according to claim 1, wherein
the bonding includes:
a step of making the first film substrate and the second film substrate face each other and intermittently conveying them in the long side direction;
a step of dividing the first film substrate or the second film substrate into a sheet form including a plurality of the circuits or the antennas at a bonding position when the conveyance is stopped; and
a step of bonding the circuits and the antennas on the first film substrate or the second film substrate in a sheet form.

7. The method for manufacturing the wireless communication device according to claim 6, wherein the first film substrate and the second film substrate are arranged so as to be orthogonal to each other.

8. The method for manufacturing the wireless communication device according to claim 1, further comprising:
a step of dividing the first film substrate into at least two or more pieces in the conveyance direction; and
a step of adjusting a distance between the divided film substrates in a direction perpendicular to the conveyance to a distance between antenna rows in a substrate width direction of the second film substrate.

9. The method for manufacturing the wireless communication device according to claim 7, further comprising:
a step of dividing the first film substrate into at least two or more in the conveyance direction; and
a step of adjusting a distance between the divided film substrates in a direction perpendicular to the conveyance to a distance between antenna rows in the conveyance direction of the second film substrate.

10. The method for manufacturing the wireless communication device according to claim 1, wherein
the circuit is formed in an array of one or more rows in a long side direction of the first film substrate in a sheet form,
the antenna is formed in an array of one or more rows in a long side direction of the second film substrate,
the second film substrate is intermittently conveyed in the long side direction to be conveyed, and
the first film substrate in the sheet form is made to face the second film substrate and the circuit and the antenna are bonded together when the conveyance is stopped.

11. The method for manufacturing the wireless communication device according to claim 6, wherein
the bonding includes:
a step of detecting an amount of displacement between the first film substrate and the second film substrate in a substrate width direction and a conveyance direction by an alignment camera; and
a step of adjusting a position of the first film substrate according to the amount of displacement.

12. The method for manufacturing the wireless communication device according to claim 1, wherein a conductive paste is applied to a connecting portion between the circuit and the antenna on the first film substrate or the second film substrate, and thereafter the bonding is performed.

13. The method for manufacturing the wireless communication device according to claim 1, wherein on the first film substrate or the second film substrate,
a non-conductive paste is applied to at least a portion between the circuit and the antenna, and thereafter the bonding is performed.

14. The method for manufacturing the wireless communication device according to claim 1, wherein the circuit is an RFID circuit.
